(19) United States
(12) Patent Application Publication
(10) Pub. No.: US 2013/0167925 A1
(43) Pub. Date: Jul. 4, 2013

(54) Mounting System for Photovoltaic Modules Having an Integrated Thermal Solar System

(71) Applicant: Ralf Roppelt, Ludwigsburg (DE)

(72) Inventor: Ralf Roppelt, Ludwigsburg (DE)

(73) Assignee: Rikker Holzbau GmbH, Affalterbach (DE)

(21) Appl. No.: 13/518,037

(22) PCT Filed: Dec. 20, 2010
(86) PCT No.: PCT/EP10/07780

§ 371 Date: Aug. 15, 2012

(30) Foreign Application Priority Data
Dec. 21, 2009 (DE) 10 2009 060 786.2

(51) Int. Cl. H01L 31/048; H01L 31/18

(52) U.S. Cl. CPC H01L 31/048; H01L 31/18
USPC 136/259; 29/890.033

(57) ABSTRACT

The invention relates to a mounting system, which is configured for mounting at least one photovoltaic module (20) and a solar collector (30) on a substructure suitable therefor. The mounting system (1) comprises at least one U-shaped mounting carrier (2) for fastening the at least one photovoltaic module (20) and for accommodating at least one solar collector (30), the U-shaped mounting support being fastened to the substructure by means of a mounting rail (3), wherein the mounting carrier (2) has support clamping receptacles (9) for fastening the at least one photovoltaic module (20) to at least one of the outer surfaces of the mounting carrier. The mounting system further comprises the at least one solar collector (30), which is accommodated in the interior of the at least one mounting carrier (2), at least one module support (11), which locks into a support clamping receptacle (9) on the mounting carrier (2), at least one module clamp (10), between which the at least one photovoltaic module (20) is fixed on the mounting carrier (2) by means of a fastening element (12), and a cover (8) for the mounting carrier (2).

### FIELD OF THE INVENTION

The present invention concerns a mounting system for photovoltaic modules which, besides having photovoltaic modules, also comprises a solar collector for hot water production.

### STATE OF THE ART

Utilizing solar radiation by means of solar collectors and photovoltaic modules has been done for some time with sometimes considerable expense and quite varying results.

From WO 2008/151783 A1 is known a light alloy profile with at least one tube element running along the profile for transporting heat-conducting media along buildings, the profile having a roof panel and base profiles that protrude from it unilaterally and delimit an intermediate space between them, at least one tube element being molded to the inside of the roof panel. Preferably, the tube element is arranged between two adjacent base profiles. A base profile should have an approximately T-shaped cross-section, with a bar that is molded onto the roof panel, and onto the other edge of which a base panel is molded.

From DE 198 37 189 C1 is known a converter device for utilizing solar energy, with which both electrical current and transportable heat energy can be extracted from solar radiation. A cylindrical concave reflector is provided for the concentration of the solar radiation, along which an array of solar cells and sections of tubes conducting heat-transporting fluid are arranged longitudinally. The solar cells are arranged on the inner, solar radiation-absorbing surface of the concave reflector, and are only partially covered in cross-section. In addition, a first tube section runs longitudinally along the outer surface of the panel of the concave reflector and is in cross-section in contact with the panel of the reflector across the breadth of the solar panel array, while, in front of the interior surface of the concave reflector, spaced from it and oriented longitudinally, a further tube section is located, connected with the first for the purposes of transport of a liquid.

From DE 101 03 835 A1 is known a solar system for utilizing solar energy with the simultaneous employment of thermal collectors and photovoltaic modules in the form of frameless elements of large surface area, connected with one another in a single level, without overlap or gaps, by means of a sealant, on a stabilizing bracket profile. The thermal collectors and photovoltaic modules are positioned with their surfaces facing one another in a specific relationship and comprise in this arrangement a whole-surface solar system.

In addition, statements in other specifications (DE 198 12 006 A1, G 91 04 211.9, DE 41 08 503 C2) refer to the combined employment of thermal and photovoltaic modules.

In all technical solutions offered thus far, however, the following points have shown themselves to be disadvantageous:

1. Design

Through combining photovoltaic and solar-thermal systems in one module, a fixed relationship between photovoltaic and solar-thermal output is provided. In this design the output ratio “electricity production to hot water requirements” cannot be flexibly adapted. Due particularly to the higher efficiency (use of a broader bandwidth of the solar spectrum) of solar-thermal systems, the focus of such systems must, for reasons of technical necessity, be on hot water heating.

2. Efficiency

As described in Point 1, the output per surface area is significantly greater for solar-thermal systems. After only a brief period of intensive exposure to sun, the water temperature is significantly higher than the recommend optimum operating temperature of photovoltaic modules (standard test conditions at 25° C.). The function, disclosed in most of the preceding patents, of cooling through the flow of the solar-thermal liquid is thus not present.

3. Heightened Risk Through the Combination of Electricity and Water in One Module

As photovoltaic systems commonly involve high voltages (up to 1,000 V), the direct proximity with water in a photovoltaic module represents a significant source of danger.

4. Weight

In consequence of the necessary shielding between the two technologies in a single module, combined modules result in significantly greater weight.

It would thus be desirable to eliminate these disadvantages and achieve an effective, simple, largely lossless and space-efficient conversion of solar energy.

### SUMMARY OF THE INVENTION

One objective of the present invention is thus to provide a simple and flexible mounting system for the combined use of thermal and electrical energy through the use of appropriate photovoltaic modules or solar collectors. A solar collector is an integral component of the mounting system. Depending on the desired solar-thermal design layout, mounting systems of the type according to this invention may be combined with mounting systems not featuring an integrated solar collector. The flexible mounting system of this invention also serves to receive standard commercially available photovoltaic modules of various sizes and thicknesses.

To this end, the present invention provides a mounting system that is configured to mount at least one photovoltaic module and one solar collector on a suitable substructure. The mounting system comprises at least one U-shaped mounting carrier fixed to the substructure via a mounting rail and used to receive the at least one photovoltaic module and the at least one solar collector, the mounting carrier for receiving the one or more photovoltaic modules featuring support clamp receptacles on at least one of its exterior surfaces. In addition, the mounting system comprises the at least one solar collector, which is received inside the at least one mounting carrier, at least one module support, which locks into a support clamp receptacle on the mounting carrier, at least one module clamp, between which the at least one photovoltaic module is fastened on the mounting carrier by means of a fastening element, and a cover for the mounting carrier.

The supporting structure may be, e.g., a roof structure. A wall mounting is also conceivable.

The cover may be made of a plastic, e.g. Plexiglas, or of glass.

In the event that no solar collector is installed in the mounting carrier, the cover could also be made of metal, e.g. aluminum.

In a further embodiment of the mounting system as disclosed in this invention, the support clamp receptacles are arranged at different heights on at least one exterior surface of the mounting carrier, allowing photovoltaic modules of differing thicknesses to be mounted.

Standard commercially available photovoltaic modules are usually found with thicknesses of approximately 2.7, 4, or 5 cm; accordingly, the support clamps are preferably designed with these thicknesses of standard commercially available photovoltaic modules in mind. Obviously, the invention is not limited to accepting such photovoltaic modules.

Together with the module supports, the module clamps have the task of fastening photovoltaic modules and solar collectors to the mounting carrier by means of a fastening element. As module clamps are positioned on the surface of photovoltaic modules and solar collectors, their size may not impede the utilization of the solar energy. At the same time, a stable installation is to be provided.

All suitable fastening elements may be used to connect a module clamp to a module support. Care must be taken to ensure that any upper part of each fastening element does not project above the upper edge of the module clamp, as shadowing, in particular of the photovoltaic module, may result.

The mounting system according to the invention permits a flexible composition of photovoltaic modules and solar collectors, as a combination or linking together of multiple such mounting systems with mounting systems without integrated solar collectors is made possible.

Different types of solar collectors may be integrated into the mounting system according to the invention. By way of example, in the following sections, one possible embodiment of a solar collector is described that is integrated into the mounting system according to the invention.

Such a solar collector consists of a U-shaped collector module, inside which are found a trough-shaped parabolic mirror and, in the area of the focal line of the parabolic mirror, two liquid-linked tube sections surrounded by a metal absorber sheet. A transparent cover serves to thermally isolate the solar collector and seal the collector module.

The trough-shaped parabolic mirror is designed to concentrate electromagnetic rays entering in parallel, such as sunlight, in the focal line. The material used must be capable of reflecting the incoming radiation to a high degree of efficiency. Suitable materials include, e.g., aluminum or stainless steel.

The arrangement of the tube sections in the center of the trough-shaped parabolic mirror ensures good heating of a heat transport fluid conducted through the tube sections. By jacketing the tube sections with a metal absorber sheet, the heating of the heat transport fluid is optimized. The absorber sheet consists of a thermally conductive metal that is either colored black or coated with an absorbent. Commonly used absorbents are selective, i.e. they are designed to absorb as efficiently as possible the shorter-wavelength solar radiation entering from outside and only minimally emit the longer-wavelength heat energy of the absorber. Absorber coatings that could be used include black chrome, nickel-pigmented aluminum oxide, or so-called “sputter coats”. The latter are produced using sputter deposition, a process in which atoms are knocked out of a solids through bombardment with high-energy ions and converted into a gas. A substrate is placed near the solid, upon which the knock-out atoms condense and form a film. Sputter coats typically employed in solar collectors consist of titanium compounds and silicon dioxide, which are applied sequentially to a metal surface.

The solar collector is also to include a transparent cover intended both to permit the solar radiation to act on the solar collector and to reduce heat loss from the solar collector.

The glass cover, which is not transparent to heat radiation, results in a ‘greenhouse effect” in the solar collector and simultaneously protects the absorber from heat loss through convection. Glass and plastic materials are frequently used for the cover. The advantage of glass lies in its having long-term stability in terms of its optical and mechanical characteristics. In general, standard window glass is not used in solar collectors, but a special solar glass featuring increased shatter resistance, greater permeability to energy-laden radiation, and decreased permeability for heat radiation emitted or reflected by the absorber. In addition, plastic materials such as Plexiglas may also be used. The advantage of plastic materials is their lower weight and greater impact resistance, which generally results in more manageable collectors.

Other possible solar collector forms and embodiments without a parabolic mirror and with a simple absorber can also be used in the collector holder.

The present invention also represents a converter device with at least one photovoltaic module and at least one solar collector, which is mounted using a mounting system describe above.

The mounting of the photovoltaic modules and solar collectors is carried out using a U-shaped mounting carrier, attached to the substructure via a mounting rail, the interior of which can accommodate a U-shaped collector module. The collector module in turn accomodates a solar collector, and is sealed against environmental influences by a transparent cover.

A module clamp is required for mounting a photovoltaic module. One end of the clamp overlaps part of the upper surface of a photovoltaic module, while the other overlaps with one surface a transparent cover and a collector module. The clamp features, for example, a hole to accommodate a screw, so that, by screwing down the screw, the module clamp presses down onto the photovoltaic module, the transparent cover, and the collector module. In addition, a height-adjustable module support is intended for fastening a photovoltaic module, configured at one end in such a manner that the one end, featuring a threaded hole to accept a screw and overlapping with the underside of a photovoltaic module, locks into a support clamp receptacle arranged on an exterior surface of the mounting carrier. The module clamp and module support are to be connected by means of a fastening element, such as a countersunk head screw, so that, when the fastening element is actuated as intended, for example, in the case of a countersunk head screw, when the screw is screwed in or down, the photovoltaic module in question is clamped between the module clamp and module support and thus fastened in place.

In being screwed down, the module clamp presses a photovoltaic module against a module support and, simultaneously, applicable corresponding transparent cover and a collector module against an upper edge of the mounting carrier, thus securing these elements.

To provide an even more flexible system, support clamp receptacles are located at various heights of the exterior surfaces of the mounting carrier facing the photovoltaic modules, so that photovoltaic modules of varying thickness can be mounted without difficulty.

The present invention also makes available a process for the mounting of at least one photovoltaic module and at least one solar collector, in which a U-shaped mounting carrier featuring support clamp receptacles on its exterior surfaces and enclosing at least one solar collector is first attached to a substructure by means of a mounting rail. In the next step, the at least one solar collector and the mounting carrier are covered with a transparent cover. As a further step, the at least one photovoltaic module is positioned between a module support, which locks into one of the support clamp receptacles on the mounting carrier, and a module clamp, which overlaps a part of the at least one photovoltaic module, the at least one solar collector, and the cover, the module support and module clamp being connected by means of a fastening element. Finally, the at least one photovoltaic module is fastened in place through appropriate actuation of the fastening element.

Additional advantages and variants of the invention may be drawn from the description and accompanying diagram.

It is evident that the features mentioned above and those yet to be explained below may be applied not only in the combinations indicated, but also in other combinations or individually, without exceeding the scope of the present invention.

### BRIEF DESCRIPTION OF THE DIAGRAMS

The figures are described comprehensively and coherently; the same reference number applies to the same component.

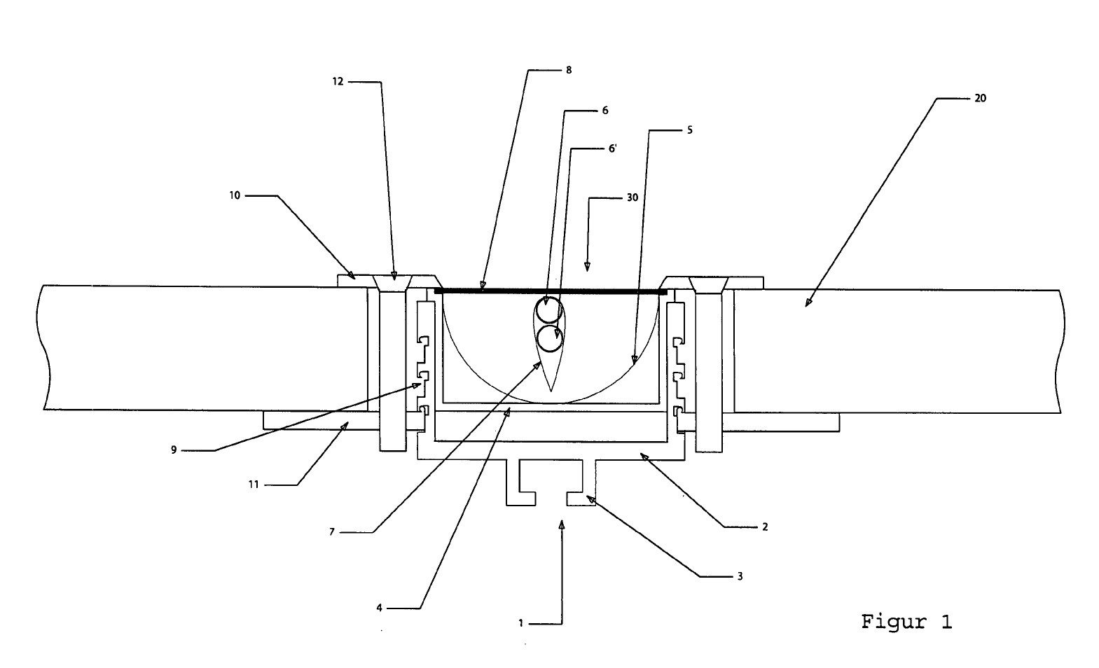

FIG. 1 shows in a schematic representation a cross-section of one embodiment of a mounting system according to the present invention with an integrated solar collector and photovoltaic modules installed.

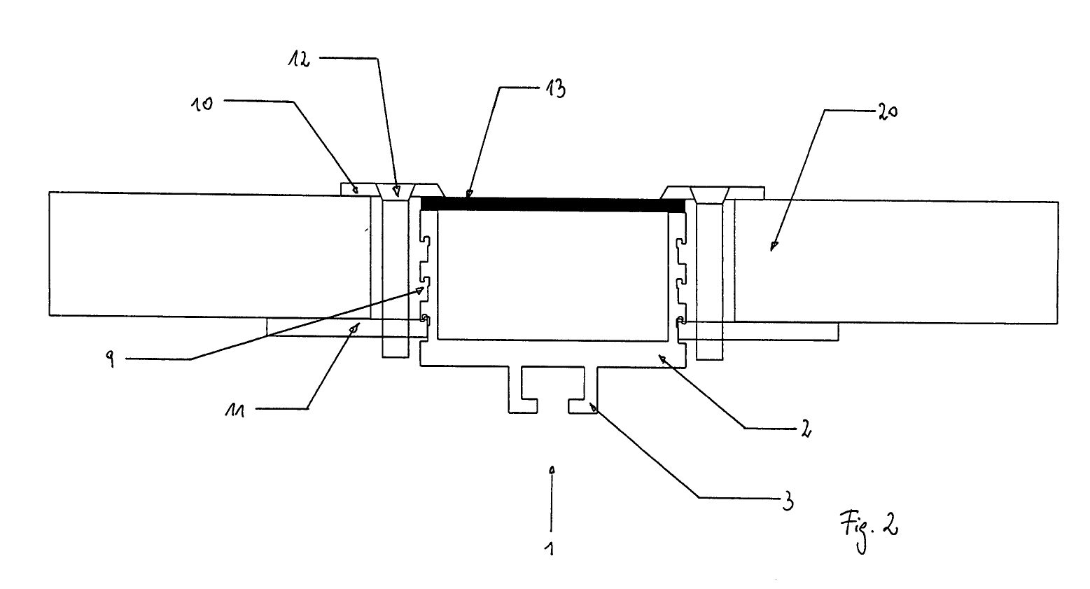

FIG. 2 shows a cross-section of another embodiment of a mounting system according to this invention without an integrated solar collector.

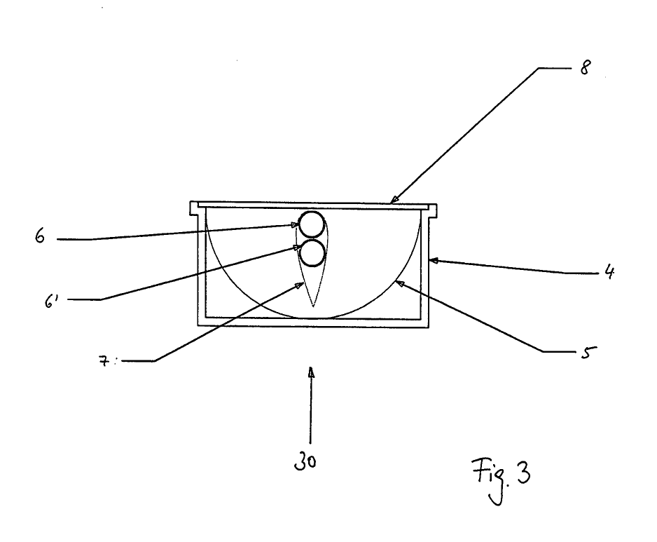

FIG. 3 shows a cross-section of an embodiment of a solar collector which may be integrated into a mounting system according to this invention.

### DETAILED DESCRIPTION OF THE DRAWINGS

FIG. 1 shows a cross-section of an embodiment of a mounting system according to the invention 1. The photovoltaic modules 20 are fastened to a substructure (not depicted) by means of a mounting carrier 2. To this end, it features a mounting rail 3. Mounting support 2 features a U-shaped profile to accept a solar collector 30. In the embodiment shown here, the solar collector 30 is an integral component of the mounting system 1, i.e. the solar collector 30 is already integrated in the mounting system 1 when the photovoltaic modules 20 are installed. First, an also U-shaped collector module 4 is inserted Into the interior of the mounting carrier 2. Inside the collector module 4 are a trough-shaped parabolic mirror 5 and, in the area of the focal line of the parabolic mirror 5, two liquid-linked tube sections 6,6′, which are jacketed with a metal absorber sheet 7. Thermal isolation of the solar collector is provided by a transparent cover 8, which seals the collector module 4.

To fasten in place the photovoltaic modules 20, support clamp receptacles 9 are arranged at different heights on both exterior surfaces of mounting carrier 2. In this way, photovoltaic modules 20 of varying thicknesses may be attached to mounting carrier 2. Fastening is carried out through screwing a module clamp 10 to a module support 11, between which a photovoltaic module 20 is held. The module support 11 supports a photovoltaic module 20 from beneath, and is held in place by locking into a suitable module support 11. The module clamp 10 supports a photovoltaic module from above and presses it against the module support 11 by means of a countersunk head screw 12. The module clamp 10 is installed in such a manner that, by screwing it down, the transparent cover 8 of the collector module and the collector module 4 itself are pressed against an upper edge of the mounting carrier 2 and thus held in place.

FIG. 2 shows a cross-section of an embodiment of a mounting system according to the invention 1. The solar collector integrated into the mounting system is not depicted here. Two photovoltaic modules 20 are fastened to a substructure (not shown) by means of a mounting carrier 2. To this end, the mounting carrier features a mounting rail 3. In contrast to the embodiment described in FIG. 1, no solar collector is depicted inside the mounting carrier 2. The mounting carrier 2 is covered by a cover 13. The fastening of the photovoltaic modules 20 and of the cover 13 is carried out analogously to that of the embodiment described in FIG. 1 through the appropriate interaction of the existing module clamps 10, support clamp receptacles 9, and module supports 11.

FIG. 3 shows a cross-section of an embodiment of a solar collector 30, which may be integrated into a mounting system according to the invention 1. The solar collector 30 consists of a U-shaped collector module 4, the interior of which contains a trough-shaped parabolic mirror 5 and, in the area of the focal line of the parabolic mirror 5, two liquid-linked tube sections 6,6′, which are jacketed with a metal absorber sheet 7. Thermal isolation of the solar collector is provided by a transparent cover 8, which seals the collector module 4.

1. Mounting system for mounting at least one photovoltaic module and one solar collector on a substructure, the mounting system comprising:
a) at least one U-shaped mounting carrier attached to the substructure via a mounting rail, for attaching the at least one photovoltaic module and for receiving at least one solar collector, the mounting carrier having support clamp receptacles for fastening the at least one photovoltaic module on at least one of its external surfaces;
b) the at least one solar collector that is received on the inside of the at least one mounting carrier;
c) at least one module support that locks into a support clamp receptacle on the mounting carrier, and at least one module clamp, between which the at least one photovoltaic module is attached to the mounting carrier using a fastening element; and
d) a cover for the mounting carrier.

2. Mounting system according to claim 1, in which the support clamp receptacles are provided at different heights on the at least one external surface of the mounting carrier, so that photovoltaic modules of different thickness can be attached.

3. Converter device with at least one photovoltaic module and at least one solar collector, which are mounted using a mounting system, said mounting system comprising:
a) at least one U-shaped mounting carrier attached to the substructure via a mounting rail, for attaching the at least one photovoltaic module and for receiving at least one solar collector, the mounting carrier having support clamp receptacles for fastening the at least one photovoltaic module on at least one of its external surfaces;
b) the at least one solar collector that is received on the inside of the at least one mounting carrier;
c) at least one module support that locks into a support clamp receptacle on the mounting carrier, and at least one module clamp, between which the at least one photovoltaic module is attached to the mounting carrier using a fastening element; and
d) a cover for the mounting carrier.

4. Method for mounting at least one photovoltaic module and at least one solar collector, comprising:
a) attaching a U-shaped mounting carrier, which has on its external surface support clamp receptacles and in its interior the at least one solar collector, to a substructure by means of a mounting rail;
b) covering the at least one solar collector and the mounting carrier by a transparent cover;
c) positioning the at least one photovoltaic module between a module support, which locks into one of the clamp receptacles on the mounting carrier, and a module clamp, which partially overlaps the at least one photovoltaic module, the at least one solar collector and the cover (8), the module support and the module clamp being connected by a fastening element; and
d) attaching the at least one photovoltaic module by appropriate actuation of the fastening element.
